(19) United States
(12) Patent Application Publication
(10) Pub. No.: US 2025/0046564 A1
(43) Pub. Date: Feb. 6, 2025

(54) CHARGED PARTICLE BEAM APPARATUS

(71) Applicant: KOREA RESEARCH INSTITUTE OF STANDARDS AND SCIENCE, Daejeon (KR)

(72) Inventors: Takashi OGAWA, Daejeon (KR); In Yong PARK, Daejeon (KR); Jeong Woong LEE, Daejeon (KR)

(73) Assignee: KOREA RESEARCH INSTITUTE OF STANDARDS AND SCIENCE, Daejeon (KR)

(21) Appl. No.: 18/519,810

(22) Filed: Nov. 27, 2023

(30) Foreign Application Priority Data
Aug. 4, 2023 (KR) 10-2023-0102422

(51) Int. Cl. H01J 37/147; H01J 37/08; H01J 37/20; H01J 37/22; H01J 37/24; H01J 37/244; H01J 37/28

(52) U.S. Cl. CPC H01J 37/1471; H01J 37/08; H01J 37/20; H01J 37/222; H01J 37/243; H01J 37/244; H01J 37/28

(57) ABSTRACT

A charged particle beam apparatus includes: a stage on which a sample is placed; a first charged particle beam unit comprising a charged particle source, a detector, and a first objective lens configured to irradiate a sample with a charged particle beam of charged particles generated by the charged particle source and induce secondary electrons generated from the sample to the detector; and a second charged particle beam unit comprising a second objective lens. An incoming electric field is generated between the first objective lens and the sample to pull the secondary electrons into the first objective lens. An induced electric field is generated between the second objective lens and the sample to guide the secondary electrons to travel to the detector.

### CROSS REFERENCE TO RELATED APPLICATION

The present application claims priority to Korean Patent Application No. 10-2023-0102422 (filed Aug. 4, 2023), which is hereby incorporated by reference in its entirety.

### BACKGROUND

The present disclosure generally relates to a charged particle beam apparatus.

A charged particle beam apparatus is configured to determine characteristics of a sample by imaging the sample by irradiating the surface of the sample with charged particles emitted from a charged particle source by means of a charged particle optical system using a magnetic or electric field. The charged particle beam apparatus is widely used in the fields of materials science, nanoscience, electronics, etc. Microscopy based on the charged particle beam apparatus has a superior spatial resolution to enable the observation of microstructures such as thin films grown on substrates, nanotubes, plasmonic structures, and atomic arrangements of samples not observable in optical microscopy. In addition, the charged particle beam apparatus may also serve to observe the microstructure of biological samples such as cells, determine the crystal structure of samples and the like through electron diffraction imaging.

Among charged particle beam apparatuses, a scanning electron microscope (SEM) is configured to use an electron source as a charged particle source equivalent to the light source of an optical microscope, scan a sample with a focused beam of electrons, and detect signal electrons to form a microscopic image. Recently, scanning electron microscopy has been focused on observations in low-energy electron beam conditions that may improve information obtained from sample surfaces and may avoid electrification of or damage to the sample.

A low-energy electron beam may degrade the resolution of the charged particle beam apparatus by increasing chromatic aberration due to the energy width or diffraction aberration due to the wavelength of the electron beam. In order to overcome or reduce the problem, scanning electron microscopes including objective lenses with low aberration coefficients capable of reducing the focal distance to the sample and improving the resolution are being developed.

The foregoing is intended merely to aid in the understanding of the background of the present disclosure, and is not intended to mean that the present disclosure falls within the purview of the related art that is already known to those skilled in the art.

### SUMMARY

A primary electron beam travels to an objective lens on an electron beam path to be provided to and focused on a sample. The primary electron beam is decelerated by a symmetrical electric field from the objective lens in the direction of the sample, and the low-energy electron beam irradiates the sample. Secondary electrons generated from the sample are accelerated by the electric field attracted toward and into the objective lens, where the secondary electrons strike an upper detector and are detected thereby. To detect the secondary electrons, a positive high voltage may be applied to the upper electrode of the objective lens, and the lower electrode of the objective lens and the sample may be grounded. In another example, a negative high voltage may be applied to the sample and the upper electrode of the objective lens may be grounded. In another example, a combination of the above two configurations may also be used.

Values of potential are set appropriate to respective electrodes or the sample so that an electric field is generated from the objective lens in the direction of the sample and a force acts to pull electrons into the objective lens. Because the sample is placed perpendicular to the electron beam, the electric field is distributed symmetrically about the center axis of the optical system. Therefore, the trajectory of secondary electrons generated from the sample is symmetrical, not tilted in any direction, so that the secondary electrons are detected by an upper detector with high efficiency without colliding with the interior of the objective.

However, the electron beam can be incident on the sample at an incline. This configuration causes the electric field between the objective and the sample to be distributed asymmetrically due to the tiled sample, unlike when the electron beam is incident perpendicular to the sample. The asymmetrical electric field causes the secondary electrons generated from the sample to travel while being deflected in one direction. Therefore, some of the secondary electrons may strike the tip of the objective lens and the internal electrodes of the objective lens to not reach the upper detector.

Consequently, the amount of signals from the secondary electrons is reduced and the detection efficiency is reduced. In addition, the secondary electrons generated from the sample may collide with the electrodes inside the objective lens to generate new electrons, and the new signal electrons generated by the collided electrons may serve as noise and worsen the signal to noise ratio, thereby making it difficult to obtain a good scanning electron microscope (SEM) image.

One of objectives to be solved by the present disclosure is to overcome the difficulty of obtaining good SEM images due to the aforementioned degradations of the signal-to-noise ratio.

According to an embodiment of the present disclosure, provided is a charged particle beam apparatus including: a stage on which a sample is placed; a first charged particle beam unit including a charged particle source, a detector, and a first objective lens configured to irradiate a sample with a charged particle beam of charged particles generated by the charged particle source and induce secondary electrons generated from the sample to the detector; and a second charged particle beam unit including a second objective lens, wherein an incoming electric field is generated between the first objective lens and the sample to pull the secondary electrons into the first objective lens, and an induced electric field is generated between the second objective lens and the sample to guide the secondary electrons to travel to the detector.

According to another embodiment of the present disclosure, provided is a charged particle beam apparatus including: a stage on which a sample is placed; a first charged particle beam unit including a charged particle source, a first upper detector, and a first objective lens configured to provide a sample with a charged particle beam of charged particles generated by the charged particle source and induce secondary electrons generated from the sample to the first upper detector; and a second charged particle beam unit including a second objective lens and a second upper detector, wherein an incoming electric field is generated between the first objective lens and the sample to pull the secondary electrons into the first objective lens, and an induced electric field is generated between the second objective lens and the sample to guide the secondary electrons to travel to the second detector.

According to an aspect of the embodiments, the induced electric field may be generated when the sample is tilted with respect to the first charged particle beam unit.

According to an aspect of the embodiments, the charged particle beam apparatus may further include a control processing part configured to control the stage, the first charged particle beam unit, and the second charged particle beam unit. The control processing part may control the size of the induced electric field depending on a tilt angle of the sample with respect to the first charged particle beam unit.

According to an aspect of the embodiments, the incoming electric field may be generated by providing the sample with potential lower than potential applied to the first objective lens. The induced electric field may be generated by providing the second objective lens with potential lower than the potential of the sample.

According to an aspect of the embodiments, the second objective lens may include a second upper electrode and a second lower electrode. The induced electric field may be generated by providing one or more of the second upper electrode and the second lower electrode with potential lower than the potential of the sample.

According to an aspect of the embodiments, the stage, the first objective lens, and the second objective lens may be located in a single vacuum chamber.

According to an aspect of the embodiments, the first charged particle beam unit may include an SEM. The second charged particle beam unit may include one of a spectrometer and a focused ion beam system.

According to an aspect of the embodiments, the charged particle beam apparatus may further include: a drive power source configured to drive the first charged particle beam unit and the second charged particle beam unit; a control processing part configured to control the first charged particle beam unit and the second charged particle beam unit and to process detected signals; and a user terminal configured to receive commands from a user.

According to an aspect of the embodiments, the induced electric field may be controlled according to the intensity of a signal detected by one or more of the first upper detector and the second upper detector.

According to an aspect of the embodiments, an image of the sample may be formed by summing data regarding the secondary electrons detected by the first upper detector and data regarding the secondary electrons detected by the second upper detector.

According to embodiments of the present disclosure, secondary electrons may be advantageously detected with high efficiency even when the sample is tilted.

### BRIEF DESCRIPTION OF THE DRAWINGS

The above and other objectives, features, and other advantages of the present disclosure will be more clearly understood from the following detailed description when taken in conjunction with the accompanying drawings, in which:

FIG. 1 is a diagram schematically illustrating a charged particle beam apparatus according to embodiments of the present disclosure.

FIG. 2 is an example diagram schematically illustrating the operation of a charged particle beam apparatus according to an embodiment.

FIG. 3 is an example diagram schematically illustrating the operation of a charged particle beam apparatus according to another embodiment.

FIGS. 4A and 4B are example diagrams illustrating images generated by the charged particle beam apparatus according to embodiments of the present disclosure.

FIGS. 5A, 5B, and 5C are diagrams illustrating simulation results related to an embodiment.

FIGS. 6A and 6B are diagrams illustrating simulation results related to another embodiment.

### DETAILED DESCRIPTION

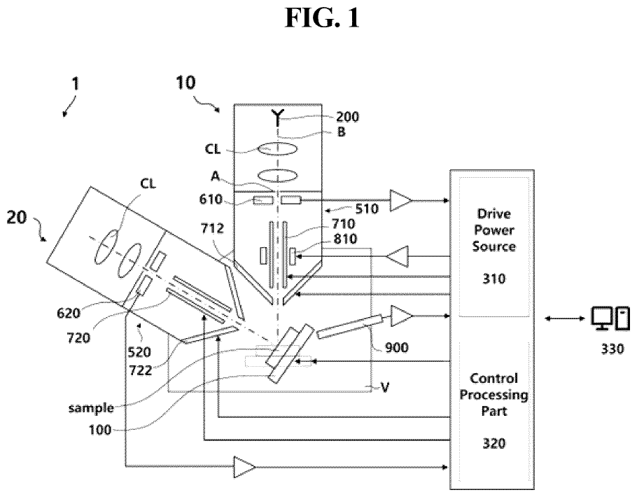

Hereinafter, embodiments of the present disclosure will be described with reference to the accompanying drawings. FIG. 1 is a diagram schematically illustrating a charged particle beam apparatus 1 according to embodiments of the present disclosure. Referring to FIG. 1, the charged particle beam apparatus 1 according to embodiments includes a stage 100 on which a sample is placed, a first charged particle beam unit 10, and a second charged particle beam unit 20. The first charged particle beam unit 10 includes a charged particle source 200, a first upper detector 610, and a first objective lens 510 configured to provide a sample with a charged particle beam B of charged particles generated by the charged particle source 200 and induce secondary electrons generated from the sample to the first upper detector 610. The second charged particle beam unit 20 includes a second objective lens 520.

In an embodiment, an incoming electric field is generated between the first objective lens 510 and the sample to pull the secondary electrons into the first objective lens 510, and an induced electric field is generated in a space between the second objective lens 520 and the sample to guide the secondary electrons to travel to the first upper detector 610.

In another embodiment, the second charged particle beam unit 20 may further include a second upper detector 620. An incoming electric field is generated between the first objective lens 510 and the sample to pull the secondary electrons into the first objective lens 510, and an induced electric field is generated in a space between the second objective lens 520 and the sample to guide the secondary electrons to travel to the first upper detector 610 and the second upper detector 620. In the illustrated embodiment, the sample, the stage 110 on which the sample is placed, the first objective lens 510, and the second objective lens 520 may be disposed in a single vacuum chamber V.

In embodiments, the charged particle beam apparatus 1 may further include a drive power source 310 configured to drive the first charged particle beam unit 10 and the second charged particle beam unit 20 by supplying drive voltages and/or current to the same and a control processing part 320 configured to control the first charged particle beam unit 10, the second charged particle beam unit 20, and the stage 100 and to process detected data regarding the secondary electrons. The charged particle beam apparatus 1 may further include a user terminal 330 configured to allow a user to input control commands to control the first charged particle beam unit 10 and the second charged particle beam unit 20 and display detection results to the user.

In an example, the first charged particle beam unit 10 may be a scanning electron microscope (SEM). The second charged particle beam unit 20 may be a spectrometer detecting elements, chemical bond states, interband transitions, phonons, or molecular vibrational states on the surface of a sample by analyzing the energy of the secondary signal electrons generated in the sample.

In another example, the second charged particle beam unit 20 may be a focused ion beam system such as focused ion beam (FIB) optics capable of etching a sample, depositing a film on the sample, and processing the sample in a region of interest (RoI) in a local scale. The arrangement state of the FIB optics may switch between a state of being tilted with respect to the stage on which the sample is placed and a state of being perpendicular to the stage. When processing the sample with focused ion beams, the surface of the sample may be oriented so that the FIB optics are perpendicular to the sample.

The sample is located on the stage 100 placed within the vacuum chamber V. in an embodiment, the stage 100 is a 5-axis stage, and the control processing part 320 may control the stage 100 in response to control commands provided by the user terminal 330 to adjust the XYZ positions, rotation, and tilt of the sample 110.

In an example, an extension of the optical axis of an optical system including the objective lens 510 of the first charged particle beam unit 10 and an extension of the optical axis of an optical system including the objective lens 520 of the second charged particle beam unit 20 intersect each other at a point referred to as a coincident point. The coincident point is a point at which the first charged particle beam unit 10 and the second charged particle beam unit 20 may operate simultaneously. Thus, the tilting of the sample and the center axis of rotation of the sample are generally designed and adjusted to correspond to the coincident point. In addition, when the first charged particle beam unit 10 is an SEM as in the illustrated example, the charged particle apparatus may be used with the sample tilted in the direction of the second optical system.

The first charged particle beam unit 10 includes the charged particle source 200. In an embodiment, the charged particle source 200 includes a filament configured to be heated to emit electrons, a suppressor electrode configured to prevent the emission of charged particles in any direction, an extractor electrode configured to pull the charged particles in a desired direction and adjust emission current, and a vacuum pump configured to create a desired vacuum within the charged particle source.

In an embodiment, each of the first charged particle beam unit 10 and the second charged particle beam unit 20 includes one or more condenser lenses CL. The charged particle beam B is focused by one or more condenser lenses CL and apertures A, with the optical axis thereof being aligned by a plurality of optical axis aligners (not shown). In addition, the astigmatism of the charged particle beam B is corrected by a stigmator (not shown).

The charged particle beam B travels toward the first objective lens 510 and is focused to the sample by the first objective lens 510. In an embodiment, the first objective lens 510 is an electrostatic objective lens or a magnetic and electrostatic compound objective lens, with a first upper electrode 710 and a first lower electrode 712 being supplied with a high voltage by the drive power source 310. For example, the high voltage may be in the range of +1 to +30 kV.

In an embodiment, the first objective lens 510 includes the first upper electrode 710 and the first lower electrode 712. In an embodiment, the first charged particle beam unit 10 may further include the first upper detector 610, a scanning unit 810, and the like, in addition to the objective lens 510.

The second objective lens 520 of the second charged particle beam unit 20 may be an electrostatic objective lens or a magnetic and electrostatic compound objective lens using an electromagnetic field. The second objective lens 520 includes a second upper electrode 720 and a second lower electrode 722. In an embodiment, the second charged particle beam unit 20 may include the second upper detector 620 and the like.

The scanning unit 810 is supplied with scanning signals provided by the control processing part 320 and controls the charged particle beam B. The scanning unit 810 controls the charged particle beam B to be scanned in an XY plane of the sample.

In an embodiment, the charged particle beam apparatus 1 may further include a lower detector 900. In an embodiment, the secondary electrons generated by scanning the charged particle beam B over the sample travel in a wide range of angles. The lower detector 900 may detect the secondary electrons not pulled to the objective lenses 510 and 520 to improve detection performance.

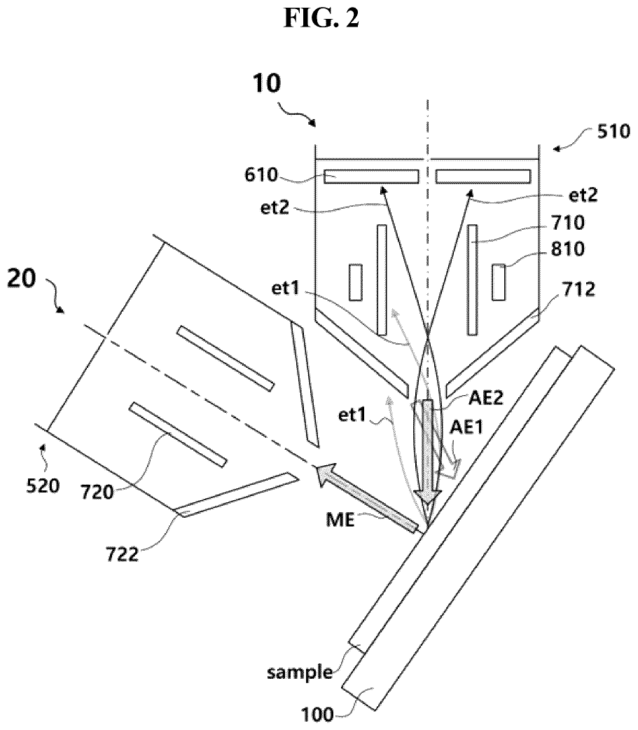

FIG. 2 is an example diagram schematically illustrating the operation of a charged particle beam apparatus 1 according to an embodiment. Referring to FIGS. 1 and 2, the charged particle beam B is accelerated between the electron source 200 and the objective lens 510 and travels in the direction of the sample. However, the primary charged particle beam focused on the sample by the objective lens 510 is decelerated by an incoming electric field between the tip of the objective lens 510 and the sample, and irradiates the sample with an energy level lower than the energy level inside the objective lens 510 to image the sample. Secondary electrons generated by irradiating the sample with the primary charged particle beam are pulled into the first objective lens 510 by the incoming electric field generated between the tip of the first objective lens 510 and the sample.

In an embodiment, the incoming electric field is generated between the first upper electrode 710 and/or the first lower electrode 712 of the first objective lens 510 and the sample, in the direction of the sample. In an embodiment, the incoming electric field may be generated as the control processing part 320 controls the drive power source 310 to supply positive potential to the first upper electrode 710 and/or the first lower electrode 712, and the sample is provided with negative potential or is grounded. In another embodiment, the incoming electric field may be generated as ground potential is provided to the first upper electrode 710 and/or the first lower electrode 712 and the sample is provided with negative potential.

When the sample is disposed with the surface thereof inclined with respect to the first objective lens 510, the incoming electric field is generated asymmetrically with respect to the charged particle beam B as indicated with a gray arrow AE1. Thus, the secondary electrons generated from the sample travel on a path et1 indicated with a gray arrow to strike the first lower electrode 712 or may be pulled into the first objective lens 510 to strike the first upper electrode 710 located inside the first objective lens 510. Consequently, the amount of signals from the secondary electrons reaching the upper detector 610 decreases, thereby lowering the detection efficiency. In another example, the secondary electrons that have struck the first upper electrode 710 may re-generate electrons, some of which may enter the first upper detector 610 to act as noise, thereby degrading the image of the sample.

The control processing part 320 controls the drive power source 310 to apply potential to the second upper electrode 720 and/or the second lower electrode 722 of the second objective lens 520 and the sample, thereby generating an induced electric field ME. The direction in which the incoming electric field is generated may be changed by the induced electric field ME, and the direction-changed incoming electric field AE2 may have a distribution generally rotationally symmetrical with respect to the first lens as in the case in which the sample is perpendicular to match or approximate the trajectory of the charged particle beam B. The secondary electrons pulled into the first objective lens 510 by the incoming electric field AE2 may strike first upper electrode 710 less frequently, and more secondary electrons may reach the first upper detector 610 to form a signal.

In an embodiment, the induced electric field ME may form the potential of the second upper electrode 720 and/or the second lower electrode 722 to be lower than the potential of the sample. Thus, the drive power source 310 may generate the incoming electric field by providing the first upper electrode 710 and/or the first lower electrode 712 and the sample with suitable voltages, and may generate the induced electric field ME by providing the second upper electrode 720 and/or the second lower electrode 722 with potential lower than the potential formed in the sample.

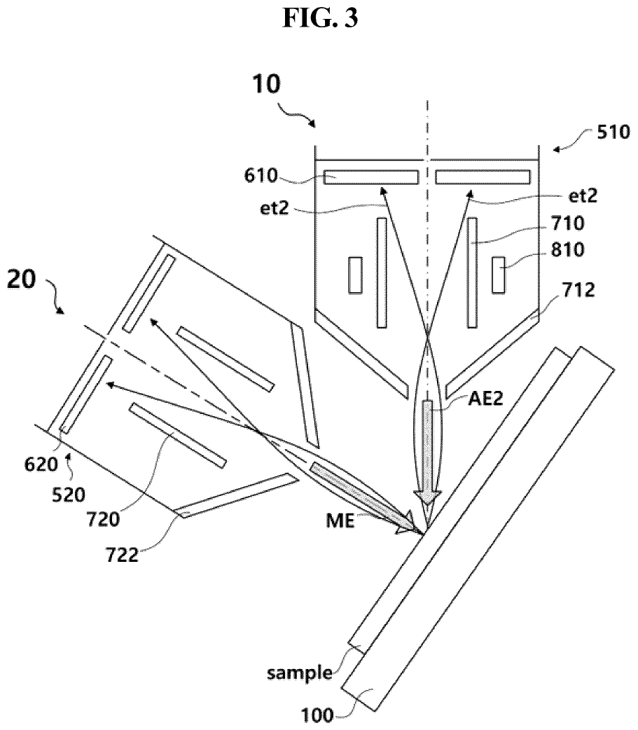

FIG. 3 is an example diagram schematically illustrating the operation of a charged particle beam apparatus according to another embodiment. Referring to FIGS. 1 and 3, the control processing part 320 controls the drive power source 310 to apply potential to second upper electrode 720 and/or the second lower electrode 722 of the second objective lens 520, thereby generating the induced electric field ME. In the embodiment illustrated in FIG. 3, the induced electric field ME may be an electric field generated from the second upper electrode 720 and/or the second lower electrode 722 of the second objective lens 520 in the direction of the sample.

The induced electric field ME illustrated in FIG. 3 may form the potential of the second upper electrode 720 and/or the second lower electrode 722 to be higher than the potential of the sample. Consequently, the drive power source 310 may generate the incoming electric field by providing the first upper electrode 710 and/or the first lower electrode 712 and the sample with suitable voltages, and may generate the induced electric field ME by providing the second upper electrode 720 and/or the second lower electrode 722 with potential higher than the potential formed in the sample.

When the induced electric field ME according to embodiments is generated, collision between secondary electrodes generated in the sample and the first upper electrode 710 of the first objective lens 510 is reduced, and more electrons reach the first upper detector 610 compared to the case in which no induced electric field is provided. Furthermore, the induced electric field ME functions similarly to the incoming electric field generated between the first objective lens 510 and the sample to pull the secondary electrons generated from the sample to the second objective lens 520. Accordingly, the second upper detector 620 included in the second charged particle beam unit 20 may detect the secondary electrons, thereby forming an image of the sample.

Returning to FIG. 1, the control processing part 320 detects the intensity of an output signal of the first upper detector 610. In an example, the control processing part 320 may include a level meter to detect the output intensity of the first upper detector 610 and adjust the potential provided to the second upper electrode 720 and/or the second lower electrode 722 depending on the output of the first upper detector 610, thereby controlling the induced electric field.

In addition, the control processing part 320 may output control signals by which the 5-axis stage is controlled so that the signal of the first upper detector 610 is the maximum at each tilt angle of the stage 100. In another example, the intensity of the induced electric field ME may be controlled depending on the tilt angle of the stage 100.

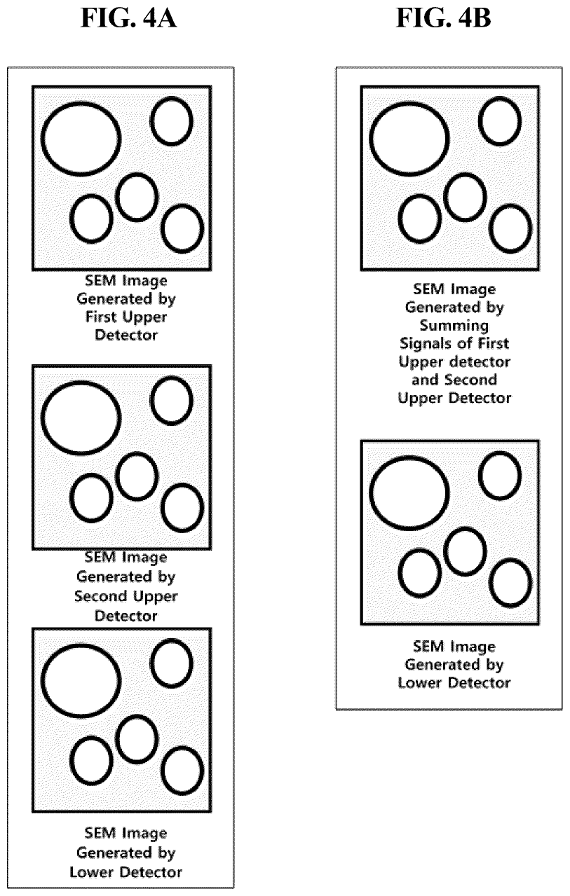

The control processing part 320 may include a frame grabber to form an image by processing data provided by the first upper detector 610 and the second upper detector 620. The frame grabber is provided with data generated by the first upper detector 610, the second upper detector 620, and/or the lower detector 900 detecting the secondary electrons, and is synchronized with a scanning signal provided by the scanning unit 810 to form an image by each detector as illustrated in FIG. 4A.

In another example, the control processing part 320 may be provided with two pieces of data formed by the first upper detector 610 and the second upper detector 620 by detecting the secondary electrons, sum the two pieces of data, and generate an image as illustrated in FIG. 4B together with a scanning signal. The lower image in FIG. 4B may be formed from data obtained by the lower detector 900 by detecting the secondary electrons. Regarding a signal from the lower detector 900, an image may be formed by synchronization with a scanning signal driver circuit. Accordingly, SEM images having different pieces of information may be simultaneously obtained from the sample by means of the detectors disposed at different positions.

### Simulation Results

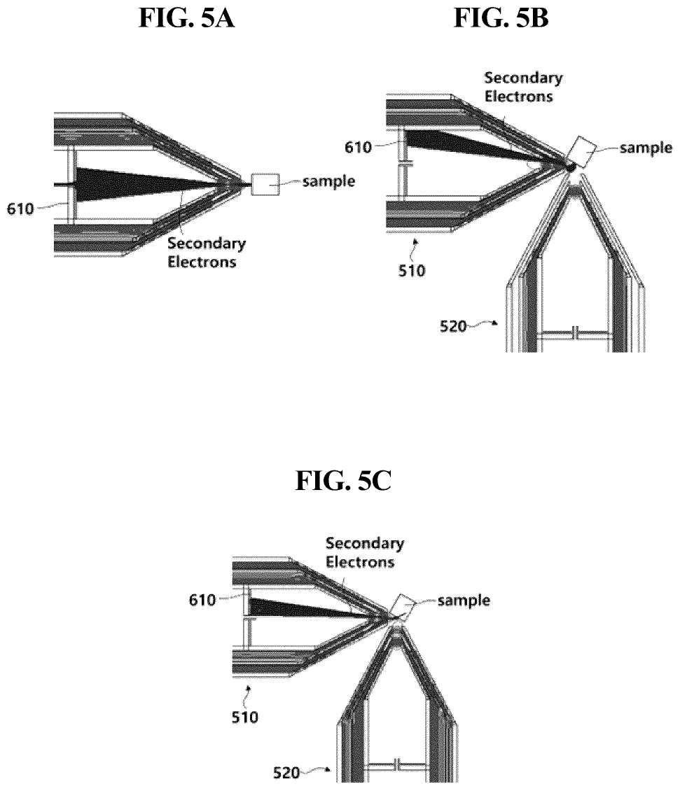

In simulation results described below, gray lines indicate equipotential surfaces, and a black line indicates the trajectory of secondary electrons generated from the sample. FIGS. 5A, 5B, and 5C are diagrams illustrating simulation results related to the embodiment illustrated in FIG. 2. In FIGS. 5A to 5C, the trajectories of the secondary electrons when a voltage was applied to a second upper electrode 720 of the second objective lens 520 were calculated, and detection efficiencies were calculated from the proportion of the secondary electrons reaching the first upper detector 610.

The simulation results will be described with reference to FIGS. 1 to 5C. FIG. 5A illustrates a case in which the sample was not tilted and the charged particle beam B was incident perpendicularly to the surface of the sample. As described above, a symmetrical incoming electric field was generated between the first objective lens 510 and the sample, and the secondary electrons were pulled into the first objective lens 510 and detected at a superior efficiency of 83.3%.

FIG. 5B illustrates a case in which the tilt angle of the stage 100 was set to 60° in order to place the sample to be tilted with respect to the first objective lens 510. In the environment illustrated in FIG. 5B, a voltage applied to the second objective lens 520 was set to be the same as a voltage applied to the sample, thereby generating no induced electric field.

When the sample was placed to be tilted as illustrated in FIG. 5B, the trajectory of the secondary electrons was significantly deflected with respect to the optical axis, and most of the secondary electrons struck the lower electrode of the objective lens or the internal electrode of the objective lens, thereby lowering the detection efficiency to 17%.

The environment of the simulation illustrated in FIG. 5C was set to be the same as the environment of FIG. 5B. The tilt angle of the stage 100 on which the sample was placed was set to 60°. Here, a voltage −3000V lower than a voltage provided to the sample was provided to the second upper electrode 720. From this, it can be seen that equipotential lines appeared from the tip of the second objective lens 520 in the direction of the sample, and an induced electric field was generated in the direction of the tip of the second objective lens 520 from the sample.

It can be seen that the deflection of the trajectory of the secondary electrons in the vicinity of the first objective lens 510 was reduced by the induced electric field as described above, and that most of the secondary electrons struck the first upper detector 610. As a result, the detection efficiency was improved to 82.6%, which is similar to that of the condition illustrated in FIG. 5A in which the secondary electrons are incident perpendicularly to the sample.

Although a voltage lower than the voltage of the sample was applied to the second upper electrode 720 in the environment of the simulation of FIG. 1, the same effect may be obtained when a voltage lower than the voltage of the sample was applied to the second lower electrode 722. In this case, a similar effect may be expected from a voltage having a smaller absolute value than when a voltage is applied to the second upper electrode 720.

The illustrated simulations showed cases of electrostatic lenses, but the same results may be obtained for an objective lens which is a compound lens of magnetic and electric fields.

Furthermore, the simulations of FIGS. 5A to 5C were performed by setting the tilt angle of the sample to 60°. For other tilt angles, an induced electric field may be generated in a similar manner by providing the second lower electrode 722 and/or the second upper electrode 720 with a voltage lower than the voltage applied to the sample and adjusting the voltage according to the tilt angle, thereby improving the detection efficiency.

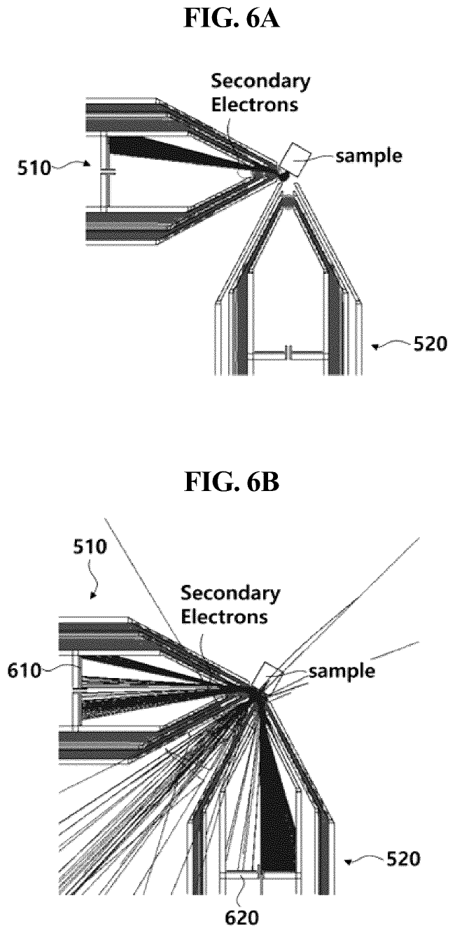

FIGS. 6A and 6B are diagrams illustrating simulation results related to the embodiment illustrated in FIG. 3. In FIGS. 6A and 6B, the trajectories of secondary electrons when a voltage was applied to the second upper electrode 720 of the second objective lens 520 were calculated, and respective detection efficiencies were calculated on the basis of the proportion reaching the first upper detector 610 and the proportion reaching the second upper detector 620. The simulations were performed by setting both the first objective lens 510 and the second objective lens 520 as electrostatic lenses.

Referring to FIGS. 1 to 6A, the voltage applied to the second objective lens 520 was the same as the voltage applied to the sample. As the sample was placed in a tilted position, the trajectory of the secondary electrons was deflected so that most of the secondary electrons struck the leading edge or the interior of the objective lens, and the detection efficiency was reduced to 17%.

In FIG. 6B, an induced electric field was generated by applying a voltage +7000 V higher than the voltage of the sample to the second upper electrode 720. In the experimental environment of FIG. 6B, as described above, secondary electrons were pulled into the closer objective lens of the first objective lens 510 or the second objective lens 520 depending on the emission angle. Here, the detection efficiency in the first upper detector 610 was 7.8% and the detection efficiency in the second upper detector 620 was 29.8%. Furthermore, the sum of the detection efficiency of the first upper detector 610 and the second upper detector 620 was 37.6%. In FIG. 6B, when a high voltage higher than the voltage of the sample was applied to the second upper electrode 720 and detected by the second upper detector 620 and when a high voltage higher than the voltage of the sample was applied to the second upper electrode 720 and detected by both the first upper detector 610 and the second upper detector 620, it can be seen that the efficiency was improved compared to the case in FIG. 6A.

A voltage higher than the voltage of the sample was applied to the second upper electrode 720 in the simulations in FIG. 6B, but a similar effect may be achieved by applying a voltage higher than the voltage of the sample to the second lower electrode 722. When a voltage is applied to the second lower electrode 722, a similar effect may be obtained from a voltage having a smaller absolute value than when a voltage is applied to the second upper electrode 720. In addition, although the calculation results in FIGS. 6A and 6B illustrate a case of electrostatic lenses, the same result may be obtained for magnetic and electrostatic compound objective lenses. In the simulations in FIGS. 6A and 6B, the calculation results are shown for the cases in which the tilt angle of the sample was 60°, but for other tilt angles, the detection efficiency may be improved by applying a voltage higher than the voltage of the sample to the second upper electrode 720 according to the tilt angle.

The present disclosure has been described with reference to the embodiments illustrated in the drawings, but these are for illustrative purposes only and those skilled in the art will understand that various modifications and other equivalent embodiments are possible therefrom. Accordingly, the true scope of technical protection of the present disclosure should be defined by the appended claims.

What is claimed is:

1. A charged particle beam apparatus comprising:
a stage on which a sample is placed;
a first charged particle beam unit comprising a charged particle source, a detector, and a first objective lens configured to irradiate a sample with a charged particle beam of charged particles generated by the charged particle source and induce secondary electrons generated from the sample to the detector; and
a second charged particle beam unit comprising a second objective lens,
wherein an incoming electric field is generated between the first objective lens and the sample to pull the secondary electrons into the first objective lens, and
an induced electric field is generated between the second objective lens and the sample to guide the secondary electrons to travel to the detector.

2. The charged particle beam apparatus of claim 1, wherein the induced electric field is generated when the sample is tilted with respect to the first charged particle beam unit.

3. The charged particle beam apparatus of claim 1, further comprising a control processing part configured to control the stage, the first charged particle beam unit, and the second charged particle beam unit,
wherein the control processing part controls the strength of the induced electric field depending on a tilt angle of the sample with respect to the first charged particle beam unit.

4. The charged particle beam apparatus of claim 1, wherein the incoming electric field is generated by providing the sample with potential lower than potential applied to the first objective lens, and
the induced electric field is generated by providing the second objective lens with potential lower than the potential of the sample.

5. The charged particle beam apparatus of claim 4, wherein the second objective lens comprises a second upper electrode and a second lower electrode, and
the induced electric field is generated by providing one or more of the second upper electrode and the second lower electrode with potential lower than the potential of the sample.

6. The charged particle beam apparatus of claim 1, wherein the stage, the first objective lens, and the second objective lens are located in a single vacuum chamber.

7. The charged particle beam apparatus of claim 1, wherein the first charged particle beam unit comprises a scanning electron microscope, and
the second charged particle beam unit comprises one of a spectrometer and a focused ion beam system.

8. The charged particle beam apparatus of claim 1, further comprising:
a drive power source configured to drive the first charged particle beam unit and the second charged particle beam unit;
a control processing part configured to control the first charged particle beam unit and the second charged particle beam unit and to process detected signals; and
a user terminal configured to receive commands from a user.

9. The charged particle beam apparatus of claim 1, wherein the induced electric field is controlled according to the intensity of a signal detected by the detector.

10. A charged particle beam apparatus comprising:
a state on which a sample is placed;
a first charged particle beam unit comprising a charged particle source, a first upper detector, and a first objective lens configured to provide a sample with a charged particle beam of charged particles generated by the charged particle source and induce secondary electrons generated from the sample to the first upper detector; and
a second charged particle beam unit comprising a second objective lens and a second upper detector,
wherein an incoming electric field is generated between the first objective lens and the sample to pull the secondary electrons into the first objective lens, and
an induced electric field is generated between the second objective lens and the sample to guide the secondary electrons to travel to the second detector.

11. The charged particle beam apparatus of claim 10, wherein the induced electric field is generated when the sample is tilted with respect to the first charged particle beam unit.

12. The charged particle beam apparatus of claim 10, further comprising a control processing part configured to control the stage, the first charged particle beam unit, and the second charged particle beam unit,
wherein the control processing part controls the strength of the induced electric field depending on a tilt angle of the sample with respect to the first charged particle beam unit.

13. The charged particle beam apparatus of claim 10, wherein the incoming electric field is generated by providing the sample with potential lower than potential applied to the first objective lens, and
the induced electric field is generated by providing the second objective lens with potential higher than the potential of the sample.

14. The charged particle beam apparatus of claim 10, wherein the second objective lens comprises a second upper electrode and a second lower electrode, and
the induced electric field is generated by providing one or more of the second upper electrode and the second lower electrode with potential higher than the potential of the sample.

15. The charged particle beam apparatus of claim 10, wherein the stage, the first objective lens, and the second objective lens are located in a single vacuum chamber.

16. The charged particle beam apparatus of claim 10, wherein the first charged particle beam unit comprises a scanning electron microscope, and
the second charged particle beam unit comprises one of a spectrometer and a focused ion beam system.

17. The charged particle beam apparatus of claim 10, further comprising:
a drive power source configured to drive the first charged particle beam unit and the second charged particle beam unit;
a control processing part configured to control the first charged particle beam unit and the second charged particle beam unit and to process detected signals; and
a user terminal configured to receive commands from a user.

18. The charged particle beam apparatus of claim 10, wherein the induced electric field is controlled according to the intensity of a signal detected by one or more of the first upper detector and the second upper detector.

19. The charged particle beam apparatus of claim 10, wherein an image of the sample is formed by summing data regarding the secondary electrons detected by the first upper detector and data regarding the secondary electrons detected by the second upper detector.
